(19) United States
(12) Patent Application Publication
(10) Pub. No.: US 2010/0015014 A1
(43) Pub. Date: Jan. 21, 2010

(54) Mixed Ionic and Electronic Conducting Membrane

(76) Inventors: Srikanth Gopalan, Westborough, MA (US); Uday B. Pal, Dover, MA (US); Karthikeyan Annamalai, Quincy, MA (US); Cui Hengdong, Allston, MA (US)

Correspondence Address: WILMERHALE/BOSTON, 60 STATE STREET, BOSTON, MA, 02109, US

(21) Appl. No.: 12/088,553

(22) PCT Filed: Sep. 29, 2006
(86) PCT No.: PCT/US06/37826

§ 371 Date: Dec. 3, 2008

Related U.S. Application Data
(60) Provisional application No. 60/721,801, filed on Sep. 29, 2005.

(51) Int. Cl. B01J 35/00; B32B 3/26; B01J 19/00; G01R 31/26

(52) U.S. Cl. 422/187; 502/4; 428/304.4; 324/719

(57) ABSTRACT

A composite membrane includes a mixed ionic and electronic conducting membrane; and an porous catalyst layer on at least one surface of the membrane, said electrocatalytic layer comprised of an oxygen ion conductor and electronic conductor.

### RELATED APPLICATIONS

This application claims the benefit of priority to co-pending U.S. application Ser. No. 60/721,801, filed Sep. 29, 2005, entitled “Surface Exchange Electrocatalysts For Ceramic Membrane Based Steam-Methane Reformation,” the contents of which are incorporated by reference.

### STATEMENT OF GOVERNMENT SUPPORT

This invention was made with Government Support under Contract Number DE-FC26-03NT41958 awarded by the Department of Energy. The Government has certain rights in the invention.

### BACKGROUND

Mixed ionic and electronic conducting (MIEC) membranes are presently being considered for a wide variety of gas separation applications including oxygen separation, partial oxidation of methane, and hydrogen separation. Hydrogen generation and separation based on mixed oxygen ion and electron conducting oxides has been reported. In this process, one side of an oxygen ion and electron conducting MIEC membrane is exposed to steam and the other side to a hydrocarbon such as methane. This sets up a chemical potential gradient in O₂ across which transport of oxygen occurs from the steam side to the hydrocarbon side leaving behind a H₂ rich product on the steam side and a product rich in syn-gas on the hydrocarbon side of the membrane. Hydrogen separation and purification using MIEC membranes are described in published PCT application WO 03/089117, which is incorporated in its entirety by reference.

In all such gas separation applications involving MIECs, both bulk transport of charged species (oxygen ions, electrons and/or holes) and surface exchange reactions on either side of the membrane control the overall flux of oxygen through the membrane. Decreasing the membrane thickness reduces the resistance of the membrane and enhances the oxygen flux. This is illustrated schematically in FIG. 1, which shows the plot of oxygen flux vs. membrane thickness. The plot shows that flux increases as the thickness of the MIEC membrane decreases, but only up to a point. Below a certain critical thickness (L_{c}) dictated by the oxygen chemical diffusion coefficient (\tilde{D}) and the oxygen surface exchange coefficient (Kₑₓ) defined as L_{c}=\tilde{D}/Kₑₓ, further reduction in thickness alone will not improve oxygen flux.

Improvements in oxygen flux across the MIEC membrane would help improve the efficiency of gas separation processes.

### SUMMARY

A surface exchange electrocatalyst is provided that significantly improves the rate of surface exchange reactions when applied to mixed ionic and electronic conducting (MIEC) membranes. Composite membranes including a porous catalyst coating and a substantially non-porous mixed ionic and electronic conducting membrane are also described. The porosity, i.e. interconnected passages for transport of gases in the catalyst also provides gas-solid interfaces for surface exchange reactions to take place.

In one aspect of the invention, catalysts are identified that enhance surface exchange reactions and thereby improve the overall transport across the membrane. The catalyst includes an ionic conductor and a metal or an electronically conducting oxide.

In one or more embodiments, the catalyst composition includes a cermet and may be for example, a nickel-Gd-doped ceria (Ni-GDC), nickel-yttria-stabilized zirconia (Ni-YSZ), Pd-YSZ, Co-GDC, Co—La_{0.8}Sr_{0.2}Ga_{0.9}Mg_{0.1}O₃ and the like. Any combination of an ionic conductor and a metal or electronically conducting oxide is contemplated as within the scope of the invention.

In one or more embodiments, the catalyst layer can be self-standing or self-supporting, and can be applied to one or both surfaces of the MIEC membrane. In one or more embodiments, the catalyst is porous to permit flow and removal of gaseous products at the membrane surface and/or at the catalyst surface.

In one or more embodiments, the catalyst is supported on an inert porous or an active porous support. In one or more embodiments, the inert support is made of alumina or mullite or other materials, which do not actively participate in the electrochemical reactions of interest and may be useful for reducing material cost and further act as the mechanical support. The inert support may also have a different porosity, particle size and/or grain structure than the surface catalyst.

In one or more embodiments, a mixed porous layer comprises active catalyst and inert support. In the case of an inert porous support, the active catalyst can be impregnated into the inert porous support by vacuum infiltration of the oxides or precursor salts (followed by heating) or other means. followed by deposition of the membrane. The catalyst materials may or may not be applied to the other side of the membrane.

In the case of an active porous support, a porous substrate of the same or composition close to the MIEC membrane is fabricated. A dense MIEC membrane is then deposited on top of the support. One or both sides of the membrane may be coated with the catalyst.

In another aspect of the invention, a hydrogen purification system is provided. The system includes a source of reforming gas, a source of steam, a flow cell including a first oxidizing compartment and a second reducing compartment separated by a mixed ionic and electronic conducting membrane having a porous catalyst layer on at least one surface of the membrane, the catalyst layer is made of an ionic conductor and electronic conductor. The system also includes a conduit for directing the reforming gas across the membrane in the first compartment, a conduit for directing the steam across the membrane in the second compartment, and a condenser downstream from the second compartment for separating steam from hydrogen.

In one or more embodiments, the catalyst-coated membrane is stable at an oxygen partial pressure less than about 10⁻⁷ atm and has an electronic conductivity of at least 1 S/cm.

In another aspect, a method is provided for evaluating compositions for use as surface electrocatalysts. The method includes equilibrating a mixed ionic and electronic conducting membrane having a layer of material to be evaluated in a first oxygen partial pressure; exposing the membrane to a second oxygen partial pressure; and obtaining the electrical conductivity transient as a function of time.

### BRIEF DESCRIPTION OF THE DRAWINGS

This invention is described with reference to the figures that are described herein, which are presented for the purpose of illustration only and are not intended to be limiting of the invention.

FIG. 1 is a schematic plot of oxygen flux vs. membrane thickness for a conventional mixed ionic and electronic conducting membrane.

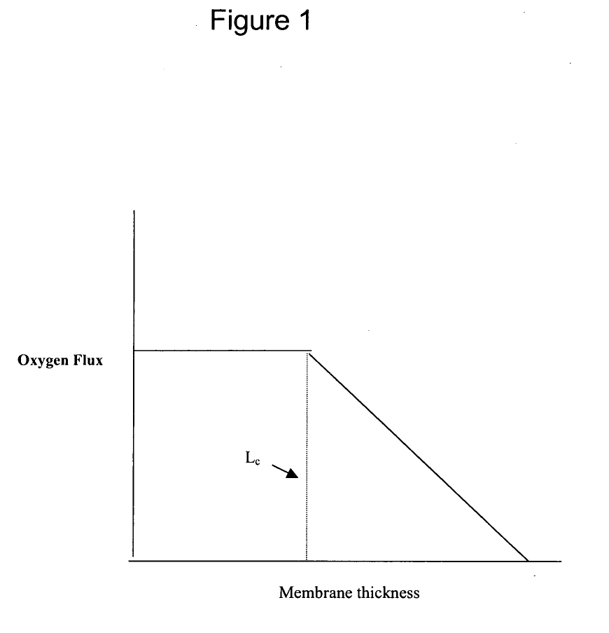

FIG. 2 is a schematic plot of oxygen flux vs. membrane thickness and illustrates the improvements in flux using a surface exchange catalyst according to one or more embodiments of the invention.

FIG. 3 is a schematic illustration of a catalyst-coated MIEC membrane according to one or more embodiments of the invention.

FIG. 4 is a schematic illustration of a catalyst-coated MIEC membrane according to one or more embodiments of the invention in which the catalyst layer serves as an active support layer.

FIG. 5 is a schematic illustration of a catalyst-coated MIEC membrane according to one or more embodiments of the invention in which an active support layer and a catalyst layer are provided.

FIG. 6 is a schematic illustration of (A) a multi-layer structure including a support and multiple catalyst layers according to one or more embodiments of the invention, and (B) an exploded view illustrating the relative particle size and porosity of the structure.

FIGS. 7A and 7B are schematic illustrations of a multi-layer structures including a support and a catalyst interpenetrating the supporting layer according to one or more embodiments of the invention.

FIG. 8 is a schematic of a Ni/GDC cermet coated 4-probe sample.

FIG. 9 illustrates conductivity transient of the bare and Ni/GDC catalyst-coated GDC-GSTA samples for (A) low and (B) high P_{O2}.

FIG. 10 is a plot of oxygen surface exchange coefficient versus oxygen partial pressure for the bare and Ni/GDC cermet catalyst coated samples.

FIG. 11 illustrates the pO₂ dependence of the oxygen chemical diffusion coefficient.

FIG. 12 illustrates J_{H}_{₂} (Area specific hydrogen generation rate) measured as a function of pH₂ on the permeate side with bare and electrocatalyst-coated samples with thickness of 0.20 mm, at reactor temperature of 900° C. and pH₂O=0.10 atm on the feed side.

FIG. 13 is a schematic illustration of a hydrogen gas apparatus according to one or more embodiments of the invention.

FIG. 14 is a schematic drawing of the experimental setup used for total conductivity and conductivity relaxation measurements.

### DETAILED DESCRIPTION

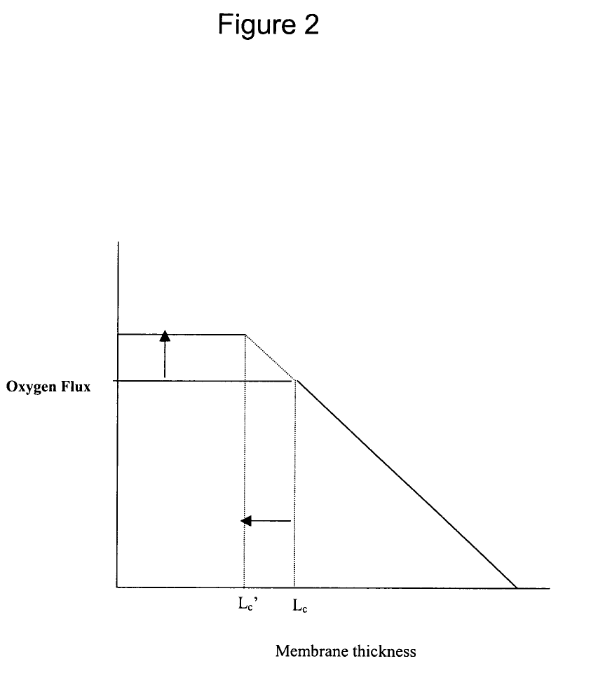

Electrocatalysts promote an electrochemical reaction at the surface of the oxide conducting membrane to form oxygen ions. The conducting electrocatalysts serve to increase surface reaction rate, so that formation of the oxygen ion at the surface is no longer the rate limiting factor for oxygen ion migration across the MIEC membrane. Further reductions in membrane thickness can then be contemplated with further improvements in oxygen flux. This is illustrated in FIG. 2, which shows the effect of the electrocatalyst on oxygen flux. As noted previously, a MIEC membrane possesses a critical thickness (L_{c}) dictated by the oxygen chemical diffusion coefficient (\tilde{D}) and the oxygen surface exchange coefficient (Kₑₓ) that is defined as L_{c}=\tilde{D}/Kₑₓ. By providing a surface catalyst, the oxygen surface exchange coefficient increases and the critical thickness, L_{c}′, decreases. Thus, the critical thickness for a catalyst-coated membrane, L_{c}′, is less than the critical thickness L_{c} for a non-coated membrane, and higher oxygen fluxes are attainable. In one or more embodiments, improvements of flux of greater than 50%, and up to 100%, as compared to uncoated membranes are observed. By appropriate selection of catalyst membranes and further modification of the membrane architecture, e.g., reductions in thickness, further improvements in oxygen permeation are possible. In one or more embodiments, improvements of oxygen permeation of greater than 100% are contemplated.

The electrocatalyst includes an ionic conductor and an electronic conductor. The oxygen ion conducting phase and the electronically conducting phases are chemically compatible with each other and stable under the temperatures and atmospheric conditions used in gas separation operations. The electrocatalyst includes a component that is electrocatalytic to the electrochemical reaction of interest. The electrochemical reaction that is of interest in the context of the electrocatalyst materials and the ECR experiments is:

H₂O (g)+2e⁻ (MIEC/electrocatalyst interface)=O²⁻ (MIEC/electrocatalyst interface)+H₂ (g)

Exemplary electronic conductors include metals, metal alloys, and electronically conducting oxides. Metals, e.g., noble metals, are known as electrocatalysts in reactions such as are relevant to gas phase separation processes. In one or more embodiments, the metal is a Group VIII metal, and may be for example, Ni, Pd, Pt, Co and/or Cu and alloys with each other or with other metals. Other metal catalyst systems that are used as surface active electrocatalysts may also be used.

Exemplary electronic oxides include complex metal oxides in which the transition metal can exist in more than one oxidation state. Mixed metal oxides having a perovskite structure (at operating temperatures) can have very good electronic conductivity. The term “perovskites” refers to a class of materials which have a structure based upon the structure of the mineral perovskite, CaTiO₃. In its idealized form, the perovskite structure has a cubic lattice in which a unit cell contains metal ions at the corners of the cell, another metal ion in its center and oxygen ions at the midpoints of the cube's edges. This is referred to as an ABO3-type structure, in which A and B represent metal ions. The metal oxide may be an n-type conductive oxides. Metal oxides in the spinel form also may be used as the electronically conductive component of the electrocatalyst.

The electronic oxide may be a donor-doped perovskite, such as donor-doped strontium titanate. The donor-doped strontium titanate may be doped at the Sr site with trivalent ions such as Gd, Y, La, Nd, Al and the like. In other embodiments, the donor doped strontium titanate has the formula RₓSr₁₋ₓTi_{1-y}R′_{y}O_{3-δ}, wherein R is a rare earth, e.g., Y, Sm, Yb, Sc, La, Gd, or Nd, R′ is Al, x is in the range of 0.01 to 0.5 and Y is in the range of 0 to 0.2. In one or more embodiments, the electronically conductive can be donor-doped indium oxides or donor-doped tin oxides, e.g., rare earth doped tin oxides and indium oxides. Exemplary electronic oxides include gadolinium and aluminum doped strontium titanate (GSTA).

The above-identified materials are believed to demonstrate some electrocatalytic activity in water vapor reduction reactions.

Exemplary oxygen ion conductors include Y₂O₃-stabilized ZrO₂, CaO-stabilized ZrO₂, Sc₂O₃-stabilized ZrO₂, Y₂O₃-stabilized CeO₂, CaO-stabilized CeO, GaO-stabilized CeO₂, ThO₂, Y₂O₃-stabilized ThO₂, or ThO₂, ZrO₂, CeO₂, or HfO₂ stabilized by addition of any one of the lanthanide oxides or CaO. In particular, rare earth doped ceria, e.g., RE₂O₃—CeO₂, where RE is a rare earth metal, e.g., Y, Gd, Sm, La, Yb, etc. may be used. Additional examples include strontium- and magnesium-doped lanthanum gallate (LSGM). Other oxides that demonstrate oxygen ion-conducting ability could be used in the surface catalyst according to one or more embodiments. 100381 In one or more embodiments, the catalyst composition includes a cermet and may be for example, a nickel-Ge-doped ceria (Ni-GDC), nickel-yttria-stabilized zirconia (Ni-YSZ), Pd-YSZ, Co-GDC, Co—La_{0.8}Sr_{0.2}Ga_{0.9}Mg_{0.1}O₃ and the like. Any combination of an ionic conductor and a metal or electronically conducting oxide is contemplated as within the scope of the invention. Typically the two components are used in substantially equal amounts (by weight); however, the ratio of ionic to electronic conductor can range from 80:20 to 20:80 vol/vol. In one ore more embodiments, the two components are present in substantially equal proportions (vol/vol).

The electrocatalyst is applied to the surface of the MIEC membrane. The MIEC membrane can be any conventional membrane that permits oxygen transport. The membranes used here are solid state ceramic membranes, which are dense and none flexible. Their thickness generally ranges from about 5-10 μm up to about 1-3 mm. These membranes separate components on the basis of coupled ionic and electronic conductivity characteristics, not on the basis of molecular size. The temperatures at which these membranes are effective are generally above 500° C., usually about 800-1000° C. The composition of MIEC membrane is similar to that of the catalyst

Gas separation processes using MIEC membranes require membranes with high chemical stability and high ambipolar conductivity, i.e., applying equally to positive and negative charges. In some embodiments, the membrane is a single phase membrane having mixed conducting properties (i.e. conduct oxygen ion and electron holes.) Suitable single phase membranes include complex oxide perovskites, La₁₋ₓSrₓCo_{y}Fe_{1-y}O_{3-δ} (LSCF) and La₁₋ₓCaₓFeO_{3-δ} (LCF), have high ambipolar conductivities and oxygen surface exchange coefficients.

In some embodiments, the membrane is a two phase material, in which the functions of ionic and electronic conduction reside in different materials. Any oxygen ion conductor and any electronic conducting material can be chosen for this purpose, and the materials are similar to those used for the electrocatalyst. In one or more embodiments, the oxygen ion conductor includes a mixed metal oxide having a fluorite structure, for example, selected from the group consisting of rare earth doped ceria, rare earth doped zirconia, rare earth doped thoria, rare earth doped hafnia and alkaline earth doped lanthanum gallium oxide. In one or more embodiments, the electronically conductive oxide includes an n-type semiconductor, or the electronically conductive oxide includes a donor-doped perovskite, for example, a donor-doped strontium titanate, or the electronically conductive oxide is selected from the group consisting of donor-doped indium oxides and donor-doped tin oxides. In one or more embodiments, the donor-doped strontium titanate has the formula RₓSr₁₋ₓTi_{1-y}R′_{y}O_{3-δ}, wherein R is a rare earth or alkaline earth element, R′ is Al, x is in the range of about 0.01 to 0.5 and Y is in the range of about 0 to 0.2.

Examples of two-phase compositions include mixtures of YSZ (ionic conductor) and Pd (or one of Pt, Ni, Ag, Au). Another example is a mixture of RE₂O₃-doped CeO₂ (ionic conductor, where RE=Y, Yb, Sc, or Gd) and Pd (or one of Pt, Ni, Ag, Au). Other examples of two-phase mixed conductors include LSGM (La₁₋ₓSrₓMg_{y}Ga_{1-y}O₃)+Ni or LSGM+Pd.

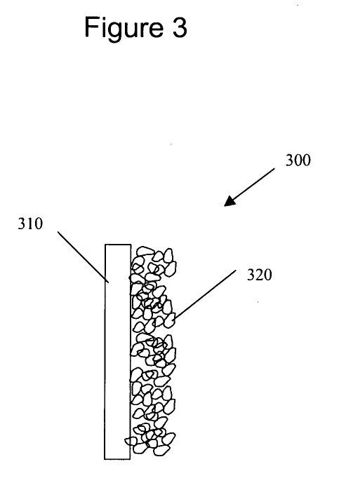

The composite catalyst can be self-standing or self-supporting, and can be applied to one or both surfaces of the MIEC membrane. The membrane can be of any shape and may be, for example, a tube or a flat membrane. In one or more embodiments, the catalyst is porous to permit flow and removal of gaseous products at the membrane surface and/or at the catalyst surface. FIG. 3 illustrates a catalyst-coated composite membrane 300 according to one or more embodiments of the present invention. The composite membrane 300 includes a dense ceramic MIEC membrane 310 such as GDC/GSTA or other mixed ionic and electronic conducting membrane. The membrane is coated with an active catalyst layer 320, that may be, for example, fine particles of a Ni-GDC cermet or other catalyst/electrocatalyst. The layer may be in the form of a porous sintered cermet. The electrocatalyst is typically in particulate or granular form and can be deposited using a variety of known methods, such as screen printing, spray coating slurry, or screen printing an ink made of a precursor to the catalyst material. The deposited layer is deposited as a precursor or in a green state and is sintered to form a porous layer.

Particle size and porosity is selected to provide a high surface area for catalysis and promote gas diffusion through the catalyst layer to the MIEC membrane surface. Exemplary porosity of the catalyst layer is in the range 5 to 50%. Exemplary catalyst layer thickness is in the range 5 microns to 1 mm. Lower thicknesses are typically appropriate when the active layer is supported by a supporting layer. Larger thicknesses are typically appropriate for embodiments in which the active layer is also serving a mechanical, supporting role. Exemplary particle size is in the range 10 nm to 10 microns.

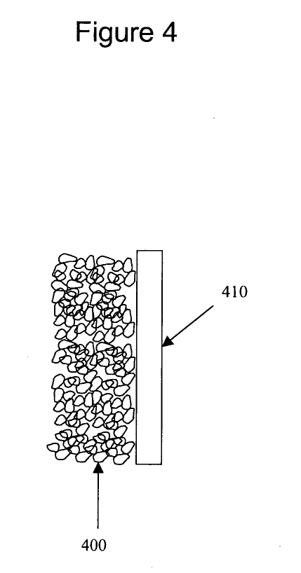

In one or more embodiments, the catalyst layer may also serve as a support, e.g., an active support layer, as is illustrated in FIG. 4. In the case of an active porous support, a porous substrate 400 of the same composition as electrocatalyst composition is fabricated. The porous support is prepared as described above for the catalyst layer; however, the support is thicker and mechanically more robust than a catalyst layer. A dense MIEC membrane 410 is then deposited on top of the support. The active support provides both surface catalysis and mechanical support of the thin, more brittle MIEC membrane.

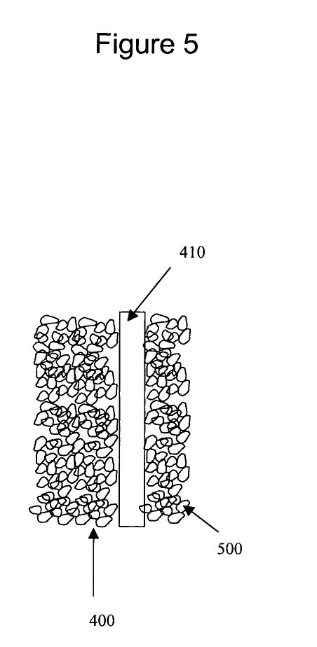

In one or more embodiments, the other side of the membrane 410 may be coated with a catalyst layer 500, as is illustrated in FIG. 5. The catalyst layer 500 may be made of the same material as the active layer 400, or it may be a different catalyst composition. Similarly, the porosity, particle size and other characteristics of the catalyst layer 500 and active layer 400 may be independently varied.

In one or more embodiments, the composite membrane includes an inert porous support. In one or more embodiments, the inert support is made of alumina or mullite or other materials, which do not actively participate in the electrochemical reactions of interest and may be useful for reducing material cost and further act as the mechanical support. The inert support may also have a different porosity, particle size and/or grain structure than the surface catalyst. Exemplary porosity of the inert support layer is in the range 5 to 50%. Exemplary catalyst layer thickness is in the range 500 microns to 1 mm. Exemplary particle size is in the range 10 nm to 10 microns.

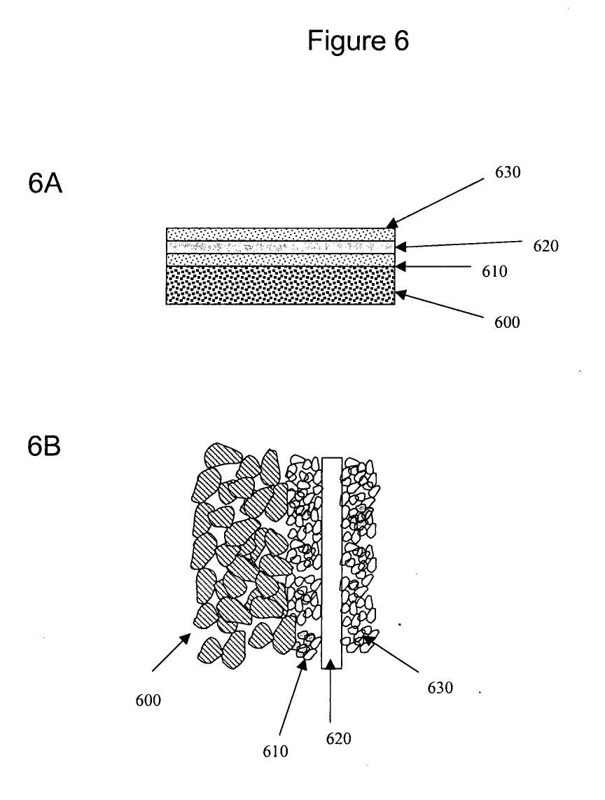

FIG. 6A illustrates a cross-sectional schematic illustration of a composite catalyst supported on an inert support according to one or more embodiments of the invention. FIG. 6B provides an exploded view of the same composite catalyst illustrating the porous nature of the layers.

A porous substrate 600 is fabricated from a heat stable, inert material. An example of a substrate is a porous composite of Gd₂O₃ (10 mol %)-CeO₂ (90 mol %) (GDC) or Gd and Al-doped SrTiO₃ (GSTA). The substrate can be fabricated using a variety of methods in the green state which include tape casting and lamination, uniaxial die pressing, and cold isostatic pressing, and then can be sintered to form a mechanically interconnected porous body.

A first porous catalyst layer 610 is deposited onto the inert substrate 600. An example of an electrocatalyst is a porous layer of Ni-GDC. The electrocatalyst can be applied onto a substrate in the green state using a variety of techniques including spray coating slurry, or screen printing an ink made of a catalyst precursor, e.g., NiO-GDC, which is converted under reducing conditions to Ni-GDC. Other techniques of application like electrophoresis may also be possible. In one or more embodiments, the conversion step is conducted at a temperature that reduces NiO to Ni metal without damaging GDC. In exemplary embodiments, the step is carried out at temperatures of less than 1300° C., e.g., 1200-1300° C., at pO₂<10⁻²⁰.

A dense MIEC membrane 620 is applied over the porous catalyst layer 610, for example, by spray coating a slurry or screen printing an organic ink made of a composite of the components of the MIEC. An example of the dense MIEC membrane is a dense two-phase material comprising ionicly conducting GDC and electronically conducting GSTA.

The electrocatalyst layer 630 on the other side of the dense membrane can also be applied by similar slurry spray coating, electrophoresis or screen printing techniques.

Each of these layer application steps may include a drying and a firing step before the application of the subsequent layers. The processing temperature for the intermediate drying and firing steps ranges from 100° C. to 1600° C. It is also possible that the entire multilayer structure can be heated and fired to the final structure in one single step or with one or more hold steps between the initial and final firing temperatures.

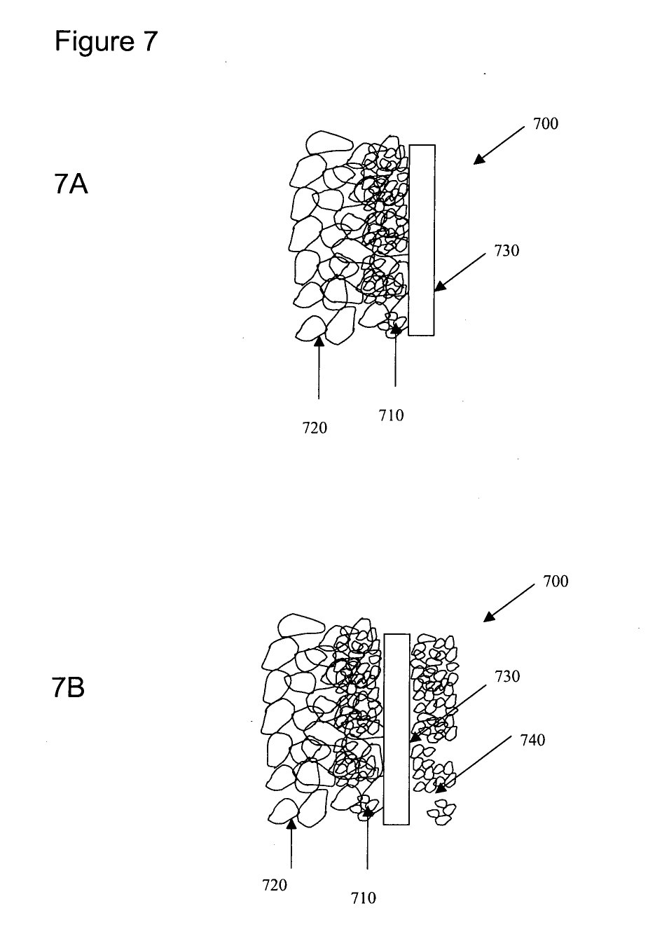

In one or more embodiments, the composite membrane 700 includes a mixed porous layer comprising active catalyst 710 and inert support 720, as is illustrated in FIG. 7.

In one or more embodiments, the active catalyst 710 can be impregnated into the inert porous 720 support by vacuum infiltration of the oxides or precursor salts (followed by heating) or other means. After the mixed layer is formed, the membrane 730 is deposited. An additional catalyst layer 740 may or may not be applied to the other side of the membrane, as illustrated in FIG. 7B. The mixed porous layer may include a homogeneous distribution of catalyst materials throughout the support layer, or the catalyst may form a graded distribution throughout the support layer or the catalyst may be localized in a selected region of the support layer. Other arrangement of the mixed porous layer are contemplated.

In one or more embodiments, the catalyst-coated membranes are used in an apparatus for hydrogen gas separation. In this process, one side of an oxygen ion and electron conducting MIEC membrane coated with a surface activating catalyst is exposed to steam and the other side to a hydrocarbon (fuel) such as methane. This sets up a chemical potential gradient in O₂ across which transport of oxygen occurs from the steam side to the hydrocarbon side leaving behind a H₂ rich product on the steam side and a product rich in syn-gas on the hydrocarbon side of the membrane. The hydrogen gas is collected from the steam at a condenser.

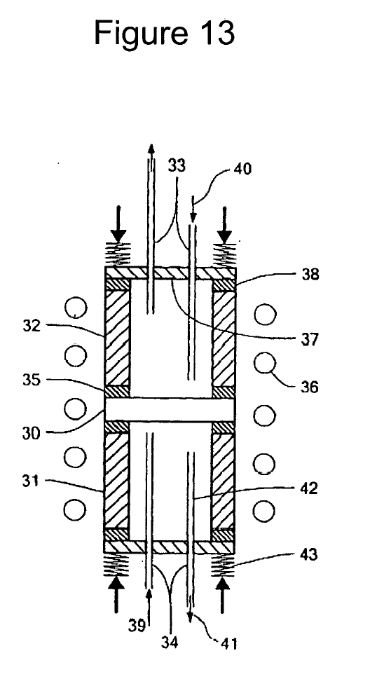

An exemplary apparatus is shown in FIG. 13. The membrane 30 is sealed between cut ends of two alumina tubes (31 and 32). Between the membrane and the ends of the tubes is placed an o-ring for sealing the membrane to the tubes. This frequently is a gold o-ring 35 that melts and forms the seal. A smaller diameter tube 33 is inserted into the syn gas side of the membrane (which is closed from the atmosphere with a stainless steel manifold 37) to carry the syn gas to the membrane, while the purified hydrogen gas is removed from the opposite side of the membrane via another tube 34. The entire apparatus is heated to 800-1000 C. with furnace heating elements 36. Typically the catalyst faces the steam side of the system but some enhancement has also been obtained on the fuel side.

For hydrogen gas separation, where the environment is more reducing than other gas separation processes, the electronically conductive oxide should be stable at an oxygen partial pressure less than about 10⁻⁷ atm. In some embodiments, the catalyst coated membrane is stable at an oxygen partial pressure in the range of 10⁻¹-10⁻²⁰ atm, or at an oxygen partial pressure in the range of 10⁻¹⁶-10⁻²⁰ atm.

In one or more embodiments, the catalyst coated membrane is stable at an oxygen partial pressure less than about 10⁻⁷ atm and has an electronic conductivity of at least 1 S/cm.

The invention is described with reference to the following examples, which are all presented for the purpose of illustration only and are not intended to be limiting of the invention.

### EXAMPLE 1

### Preparation of a Ni-GDC Coated MIEC Membrane

Porous composite cermet catalysts of Ni-GDC (Gd-doped CeO₂) were applied on previously prepared dense composite membrane comprising GSTA (Gd and Al-doped SrTiO₃)-GDC. Electrical conductivity relaxation (ECR) experiments were used to compare the rates of oxygen surface exchange of bare and catalyst-coated GSTA-GDC samples.

GDC and GSTA powders were prepared by the conventional solid state reaction/calcination route. Stoichiometric mixtures of precursor powders of Gd₂O₃, CeO₂, SrCO₃, TiO₂, and Al₂O₃ were calcined at 1300° C. for 4 hours. The calcined powders were pulverized and ball-milled to an average particle size of around 1 μm. The ball-milled powders of GDC and GSTA were then mixed in the volume ratio of 40% GDC-60% GSTA. The volume ratios were calculated using the density values obtained from the literature. The prepared mixed powders were then pressed into pellets using a pressure of around 3000-5000 psi. The pellets were first sintered in air at 1500° C. for 4 hours, and then sintered under reducing conditions (pO₂<10⁻²⁰ atm) at 1400° C. for 4 hours. All the powders and pellets were characterized using X-ray diffraction, scanning electron microscopy (SEM), and the elemental analysis by wavelength dispersive spectrometry (WDS). These results show the required formation and stability of the fluorite and perovskite structure of the GDC and GSTA phases respectively in the composite prior to and after reduction.

Selected dense GDC-GSTA composite samples were cut into rectangular bars (˜3 mm×3 mm×30 mm) and some bars were coated with the cermet catalyst of Ni/GDC (50 vol %) for electrical measurements. Calculated amounts of NiO and GDC powders were mixed with terpineol. The mixture was applied on the surface of the composite material in ˜20 micron layer and was fired in air at 800° C. for 2 hours to remove the terpineol. The coated sample was then sintered in reducing atmosphere (pO₂<10⁻¹⁰ atm) at 1300° C. for 4 hours to reduce NiO to Ni. These conditions were sufficient to obtain Ni-GDC without detrimental affect on the GDC-GSTA membrane.

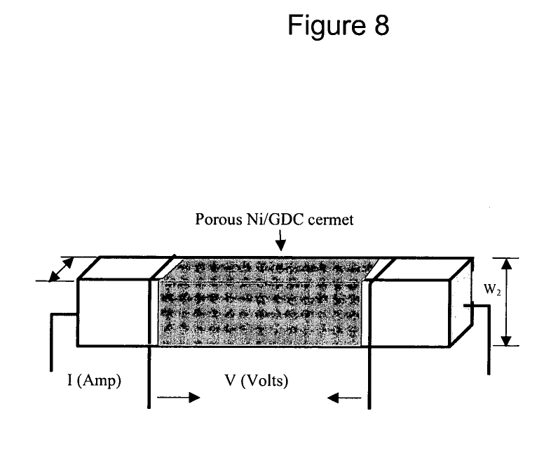

The conductivity of the sample was measured using the standard four-probe dc method, using a Solartron electrochemical system. Platinum paste was painted on the ends of the sample and platinum leads were attached to them. Voltage measurements were made at the center of the sample as shown in FIG. 8, using platinum paste and leads. A constant current was applied through the current leads and the voltage drop across the voltage leads was recorded.

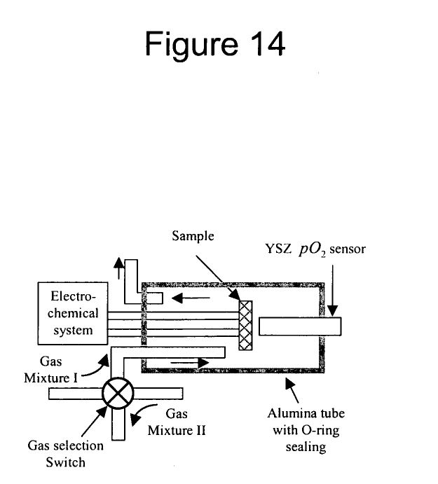

Permeation (oxygen flux) measurements with and without the surface catalyst were used to characterize properties of a catalyst and membrane respectively. An exemplary system used transient conductivity relaxation is shown in FIG. 14. The ECR technique is used as a screening tool for studying the effect of catalysts on surface exchange kinetics. The ECR technique is a quick screening method and also provides surface and bulk rates that are used to analyze the permeation properties of a membrane/catalyst. The surface catalyst rates of a test material can be compared against surface reaction rates of bare membrane or a standard catalyst in order to evaluate its catalytic effect.

The electrical conductivity relaxation (ECR) experiment was performed using the same four-probe dc measurement setup. The oxygen partial pressure was measured by an YSZ oxygen sensor which was located close to the sample. Gas with variable compositions of hydrogen, H₂O and argon were used to adjust the oxygen partial pressure, pO₂. The sample was first equilibrated at an oxygen partial pressure pO₂ (I) at a fixed applied current. The oxygen partial pressure was then abruptly changed to pO₂ (II) (within one order of magnitude of pO₂ (I)) and the electrical transient was measured as a function of time at a fixed current. The data was then converted to conductivity transient data using the cell constant of the sample. Conductivity is determined as a function of time.

Conductivity will vary based on the external P_{O2} and is a function of both bulk properties (characterized by the diffusivity coefficient, \tilde{D}) and surface properties (characterized by the surface exchange coefficient Kₑₓ). The time dependence of the fractional change in conductivity was numerically fit to obtain the chemical diffusion of oxygen (\tilde{D}) in the bulk and surface exchange (Kₑₓ) of oxygen. A well-known solution to the diffusion equation is available in the literature to obtain such curve fits and is given below:

$$\frac{( {σ}_{t} - {σ}_{o} )}{( {σ}_{∞} - {σ}_{o} )} = 1 - {\sum }_{n = 1}^{∞} {\sum }_{m = 1}^{∞} \frac{2 {L}_{1}^{2} exp ( - {β}_{m}^{2} \tilde{D} t / {W}_{1}^{2} )}{{β}_{m}^{2} ( {β}_{m}^{2} + {L}_{1}^{2} + {L}_{1} )} \times \frac{2 {L}_{2}^{2} exp ( - {β}_{n}^{2} \tilde{D} t / {W}_{2}^{2} )}{{β}_{n}^{2} ( {β}_{n}^{2} + {L}_{2}^{2} + {L}_{2} )} \qquad ( 1 )$$

In the above equation, σₜ is the conductivity at time t, σₒ the initial conductivity prior to the abrupt change in pO₂, σ_{∞} is the final conductivity after the sample equilibrates to the new atmosphere. 2W₁ and 2W₂ are the cross-sectional width dimensions of the sample and L₁=W₁/L_{c}=βₘ tan βₘ and L₂=W₂/L₂=βₙ tan βₙ, L_{c} is the critical length as given previously, and β_{i.} is the i^{th} root of the equation L=βᵢ tan βᵢ. The relaxation transients were fitted using the least squares technique to obtain \tilde{D} and Kₑₓ. The conductivity relaxation experiments were performed over a range of pO₂'s at a fixed temperature to obtain \tilde{D} and Kₑₓ as a function of pO₂.

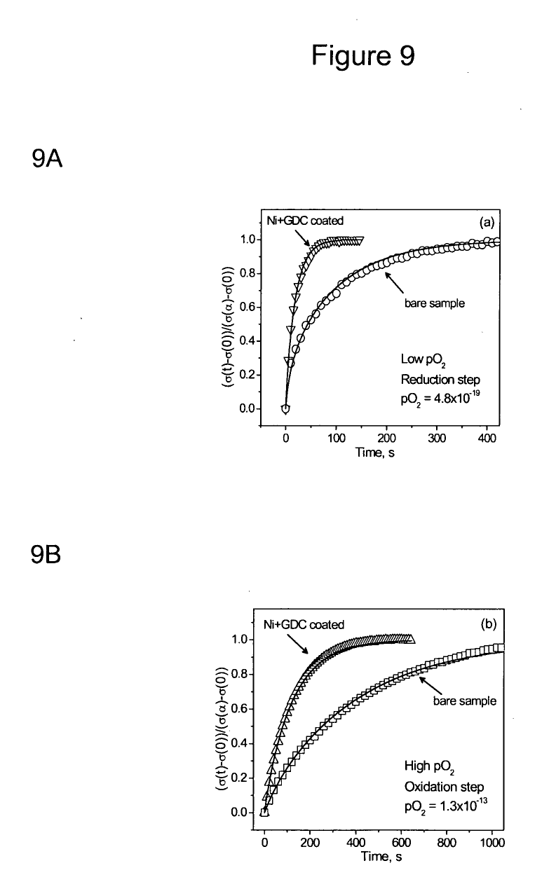

FIGS. 9A and 9B show the normalized conductivity transients of bare and Ni/GDC porous cermet coated samples at two different oxygen partial pressures, 4.8×10⁻¹⁹ and 1.3×10⁻¹³ atm at a temperature of T=900° C. These two oxygen partial pressures represents the prevailing conditions at permeate (methane) side and feed (steam) side of the membrane during the hydrogen separation process. Oxygen incorporation and removal occurs at the feed and permeate side respectively and the surface exchange rate at these two sides are governed respectively by oxidation and reduction step of the ECR experiments. As can be seen clearly application of the Ni/GDC surface catalyst led to a dramatic shortening of the time required for re-equilibration. This clearly indicates improvement in surface rates since the bulk and its dimensions remains practically same. Microscopic characterization of the Ni-GDC interface with the GDC-GSTA membrane have been carried out and no adverse interfacial effects have been notices.

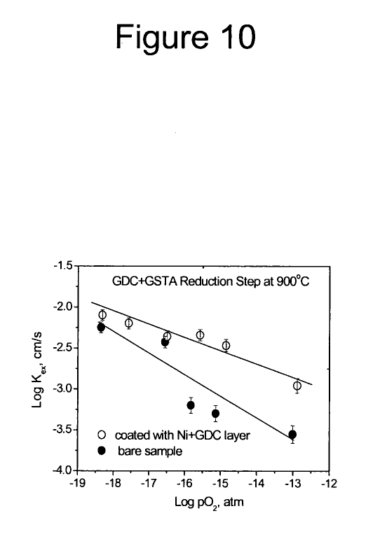

FIG. 10 shows the variation of Kₑₓ data, obtained from fitting the normalized conductivity transient with the solution to the diffusion equation, as a function of oxygen partial pressure pO₂ at 900° C. The application of the Ni/GDC cermet catalyst resulted in an enhancement of the surface exchange coefficient. Further, enhancement in oxygen surface exchange coefficient appears to be higher at higher values of pO₂. Thus in the process of interest; i.e., steam-methane reformation across an oxygen ion/electron conducting MIEC, application of a Ni/GDC porous cermet catalyst to the surface of the membrane on the steam side serves to obtain higher O₂ flux.

The surface exchange coefficient decreases with increasing pO₂. The overall reaction for oxygen incorporation into the oxide lattice in a H₂O—H₂ gas mixture can be written as:

H₂O(g)+V_{O}^{••}+2e′→H₂(g)+O_{O}^{X} (2)

This overall reaction likely proceeds through a number of intermediate steps involving adsorption, dissociation and charge-transfer. An increase in water vapor partial pressure, with a concomitant increase in pO₂, is expected to increase the surface coverage of adsorbed species. If surface adsorption was the rate controlling step in oxygen incorporation, the increase in pO₂ is expected to result in an increase in Kₑₓ. However, the experimentally measured Kₑₓ decreases with increase in pO₂. This suggests that surface adsorption is not the rate controlling step in oxygen incorporation under these experimental conditions. It is possible that an increase in oxygen vacancy concentration or mixed conduction with decreasing pO₂ could be rate controlling. Similar observations have been made on other oxide materials by other workers.

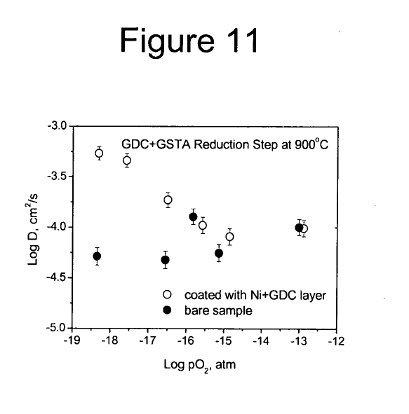

FIG. 11 shows the oxygen chemical diffusion coefficient \tilde{D} as a function of oxygen partial pressure for both the Ni/GDC catalyst-coated and bare samples. Within experimental scatter, no discernible dependence of \tilde{D} on pO₂ over the higher range of pO₂'s is evident, although in the lower ranges of pO₂'s the \tilde{D} value of the Ni/GDC catalyst-coated sample was an order of magnitude higher than that of the bare sample.

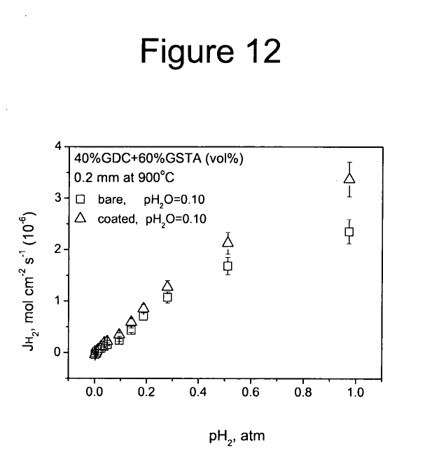

The electrical conductivity relaxation technique (ECR) can be used to screen various electrocatalyst materials for their relative effectiveness for different surface exchange reactions, as is illustrated in FIG. 12. FIGS. 12 shows J_{H}_{₂} (Area specific hydrogen generation rate) measured as a function of pH₂ on the permeate side with bare and electrocatalyst-coated samples with thickness of 0.20 mm, at reactor temperature of 900° C. and pH₂O=0. 10 atm on the feed side. When hydrogen pressure is higher, the vapor pressure (pH₂O) is lower, and the electrocatalytic limitations are greater. Thus, greater catalyst enhancement is expected when H₂/H₂O in the gas phase is higher.

As will be apparent to one of ordinary skill in the art from a reading of this disclosure, the present invention can be embodied in forms other than those specifically disclosed above. The particular embodiments described above are, therefore, to be considered as illustrative and not restrictive. In addition, the invention includes each individual feature, material and method described herein, and any combination of two or more such features, materials or methods that are not mutually inconsistent.

1. A composite membrane, comprising:
a mixed ionic and electronic conducting membrane; and
a dual phase porous catalyst layer on at least one surface of the membrane, said catalytic layer comprised of a composite material having an oxygen ion conductor and electronic conductor.

2. The composite membrane of claim 1, wherein the oxygen ion conductor of the porous catalyst is selected from the group consisting of Y₂O₃-stabilized ZrO₂, CaO-stabilized ZrO₂, Sc₂O₃-stabilized ZrO₂, Y₂O₃-stabilized CeO₂, CaO-stabilized CeO, GaO-stabilized CeO₂, ThO₂, Y₂O₃-stabilized ThO₂, or ThO₂, ZrO₂, CeO₂, and HfO₂ stabilized by addition of any one of the lanthanide oxides or CaO.

3. The composite membrane of claim 1, wherein the oxygen ion conductor is selected from the group consisting of rare earth doped ceria, e.g., RE₂O₃—CeO₂, where RE is a rare earth metal, Y, Gd, Sm, La, Yb.

4. The composite membrane of claim 1 wherein the electronic conductor is a selected from the group consisting of metals, metal alloys, and electronically conducting oxides.

5. The composite membrane of claim 4, wherein the metal is a Group VIII metal.

6. The composite membrane of claim 4, wherein the metal is selected from the group consisting of Ni, Pd, Pt, Co and/or Cu and alloys with each other.

7. The composite membrane of claim 4, wherein electronic oxide comprises a donor-doped perovskite.

8. The composite membrane of claim 7, wherein the donor-doped perovskite comprises donor-doped strontium titanate is doped at the Sr site with trivalent ions such as Gd, Y, La, Nd, Al and the like.

9. The composite membrane of claim 7, wherein the donor-doped strontium has the formula RₓSr₁₋ₓTi_{1-y}R′_{y}O_{3-δ}, wherein R is a rare earth, e.g., Y, Sm, Yb, Sc, La, Gd, or Nd, R′ is Al, x is in the range of 0.01 to 0.5 and Y is in the range of 0 to 0.2.

10. The composite membrane of claim 4, wherein the electronically conductive is selected from the group consisting of donor-doped indium oxides, donor-doped tin oxides, rare earth doped tin oxides and indium oxides, and gadolinium and aluminum doped strontium titanate (GSTA).

11. The composite membrane of claim 1, wherein the catalyst layer includes a cermet.

12. The composite membrane of claim 11, wherein the cermet is selected from the group consisting of nickel-Ge-doped ceria (Ni-GDC), nickel-yttria-stabilized zirconia (Ni-YSZ), Pd-YSZ, Co-GDC, and Co—La_{0.8}Sr_{0.2}Ga_{0.9}Mg_{0.1}O₃.

13. The composite membrane of claim 1, wherein the dual phase porous catalyst layer has a porosity in the range of 5 to 50%.

14. The composite membrane of claim 1, wherein the proportion of ionic to electronic conducting material in the porous layer ranges from 80:20 to 20:80 vol/vol.

15. The composite membrane of claim 1, further comprising a second porous catalyst layer on the opposing side of the membrane.

16. The composite membrane of claim 1, further comprising a supporting layer on the side opposing side of the membrane.

17. The composite membrane of claim 16, wherein the supporting layer is electrochemically inert.

18. The composite membrane of claim 17, wherein the inert supporting layer is selected from the group consisting of alumina, mullite, stainless steel or silicon dioxide.

19. The composite membrane of claim 16, wherein the supporting layer comprises a catalytic layer.

20. The composite membrane of claim 19, wherein the supporting layer has the same composition as the catalyst layer.

21. The composite membrane of claim 16, wherein the supporting layer has a thickness in the range 0.5-2 mm.

22. The composite membrane of claim 16, wherein the supporting layer has a porosity in the range 5 to 50%.

23. The composite membrane of claim 1, wherein the catalytic layer is of a thickness to provide mechanical support to the membrane.

24. The composite membrane of claim 23, wherein the supporting catalytic layer has a thickness in the range 0.5-2 mm.

25. The composite membrane of claim 1, wherein the catalyst layer further comprises an inert support material.

26. The composite membrane of claim 25, wherein the catalyst is localize as a location adjacent to the membrane.

27. The composite membrane of claim 25, wherein the catalyst is distributed throughout the support material.

28. The composite membrane of claim 25, wherein the catalyst forms a gradient with the inert support material.

29. A hydrogen purification system, comprising:
a source of hydrocarbon gas or reformate of hydrocarbon gas;
a source of steam;
a flow cell including a first oxidizing compartment and a second reducing compartment separated by a mixed ionic and electronic conducting membrane having a porous catalyst layer on at least one surface of the membrane, said catalyst layer comprised of an ionic conductor and electronic conductor;
a conduit for directing the reforming gas across the membrane in the first compartment;
a conduit for directing the steam across the membrane in the second compartment; and
a condenser downstream from the second compartment for separating steam from hydrogen.

30. The apparatus of claim 29, wherein the mixed ionic and electronic conducting membrane includes an oxygen ion conductor and an n-type electronically conductive oxide, wherein the electronically conductive oxide is stable at an oxygen partial pressure less than about 10⁻⁷ atm and has an electronic conductivity of at least 1 S/cm.

31. The apparatus of claim 29, wherein the catalyst composition comprises a cermet.

32. The apparatus of claim 31, wherein the cermet is selected from the group consisting of nickel-Ge-doped ceria (Ni-GDC), nickel-yttria-stabilized zirconia (Ni-YSZ), Pd-YSZ, and Co-GDC, Co—La_{0.8}Sr_{0.2}Ga_{0.9}Mg_{0.1}O₃.

33. A method of evaluating a material as a surface catalyst, comprising:
equilibrating a mixed ionic and electronic conducting membrane having a layer of material to be evaluated in a first oxygen partial pressure;
exposing the membrane to a second oxygen partial pressure; and
obtaining the electrical conductivity transient as a function of time.

34. The method of claim 33, further determining the surface exchange coefficient of oxygen based on electrical conductivity transient data.

35. The method of claim 34, further comprising comparing the determined surface exchange coefficient of oxygen against a preselected standard.
